(19) United States
(12) Patent Application Publication
(10) Pub. No.: US 2016/0181828 A1
(43) Pub. Date: Jun. 23, 2016

(54) DEVICE AND METHOD FOR CONTROLLING BATTERY

(71) Applicant: Silicon Mitus, Inc, Seongnam-si (KR)

(72) Inventor: Hojun SHIN, Palo Alto, CA (US)

(21) Appl. No.: 14/573,325

(22) Filed: Dec. 17, 2014

(51) Int. Cl. H02J 7/00; G01R 31/36

(52) U.S. Cl. CPC H02J 7/007; G01R 31/3675; G01R 31/362

(57) ABSTRACT

Provided is a method of controlling a battery that supplies power to a system, the method including: providing a discharge path, outside of the system; monitoring an ON/OFF state of the system, a terminal voltage of the battery, and an ambient temperature; and discharging the battery through the discharge path when the system is turned off, the terminal voltage of the battery exceeds a first reference voltage, and the ambient temperature exceeds a reference temperature.

### BACKGROUND OF THE INVENTION

1. Field of the Invention

The present invention relates to a method of monitoring and controlling a battery when a system is turned off.

2. Description of the Prior Art

A battery is a device for converting chemical energy into electrical energy, and recently, has been broadly applied in various applications, such as smart phones, tablet computers, electric vehicles, and the like.

The battery is advantageous in that it can readily store a large amount of electrical energy in a small space, but may be dangerous in that it may explode or become inflated when it becomes unstable.

A battery may become chemically unstable state for various reasons, for example, over charge, over voltage, over current, and the like.

The over charged state may be identified indirectly through the voltage of the battery. For example, when the voltage of the battery is greater than or equal to a predetermined voltage, the corresponding battery may be assumed to be in an over charged state.

Accordingly, the conventional art monitors the voltage and the current of the battery so as to check whether the battery is chemically unstable.

The chemically unstable state of the battery may be resolved through discharge. As a matter of course, when an amount of the discharge is large, the chemically unstable state may be caused by over current. However, when the battery is discharged based on a current that is less than or equal to a predetermined value, the chemically unstable state incurred by other causes such as over charge, over voltage, or the like is highly likely to be resolved.

While a system connected to the battery is being operated, the battery is continuously discharged by the system. Therefore, although the battery is temporarily in a chemically unstable state, the problem is highly likely to be removed.

However, in a state in which the system is turned off, when the battery is chemically unstable, there is no method for resolving the unstable state, which is a drawback.

In addition, the conventional art fails to include a configuration for monitoring the status of the battery when the system is turned off and thus, it is difficult to recognize whether the battery is chemically unstable or not.

### SUMMARY OF THE INVENTION

In this background, an aspect of the present invention is to provide a method of monitoring the status of a battery when a system is turned off.

Another aspect of the present invention is to provide a method of discharging a battery when a system is turned off.

In accordance with an aspect of the present invention, there is provided a battery controlling device that supplies power to a system. The battery controlling device includes: a first power switch that is connected to a terminal of the battery and has an on-state resistance; a first logic circuit that outputs a first signal when a terminal voltage of the battery exceeds a reference voltage; a second logic circuit that outputs a second signal when an ambient temperature exceeds a reference temperature; and a discharge control circuit that turns the first power switch on when the system is turned off and the first signal and the second signal are received, so as to discharge the battery.

In accordance with another aspect of the present invention, there is provided a battery controlling method that supplies power to a system. The battery controlling method includes: providing a discharge path, outside of the system; monitoring an ON/OFF state of the system, a terminal voltage of the battery, and an ambient temperature; and discharging the battery through the discharge path when the system is turned off, the terminal voltage of the battery exceeds a first reference voltage, and the ambient temperature exceeds a reference temperature.

In accordance with the other aspect of the present invention, there is provided a battery controlling device that supplies power to a system. The battery controlling device includes: a current source that is connected to a terminal of the battery and has an on-state resistance; a first logic circuit that outputs a first signal when the terminal voltage of the battery exceeds a reference voltage; a second logic circuit that outputs a second signal when an ambient temperature exceeds a reference temperature; and a discharge control circuit that controls the current source when the system is turned off and the first signal and the second signal are received, so as to discharge the battery.

As described above, according to the present invention, the status of a battery may be monitored while the system is turned off, and the battery may be discharged based on a result of monitoring, so as to make the battery stable.

### BRIEF DESCRIPTION OF THE DRAWINGS

FIG. 1 is a diagram of an application according to an embodiment of the present invention;

FIG. 2 is a diagram of an example of a controller 130 of FIG. 1;

FIG. 3 is a graph illustrating a hysteresis property of a battery voltage comparer C1 of FIG. 2;

FIG. 4 is a diagram illustrating a circuit model of a power switch Q1 of FIG. 2;

FIG. 5 is a diagram of another example of a discharge circuit;

FIG. 6 is a flowchart of an example of a battery controlling method;

FIG. 7 is a diagram of an example of a battery discharge controlling operation;

FIG. 8 is a diagram of an application according to another embodiment of the present invention;

FIG. 9 is a diagram of another example of the battery discharge controlling operation of FIG. 6; and

FIG. 10 is a diagram of an example of a switch-mode charging circuit;

FIG. 11 is a diagram of another example of a controller 130 of FIG. 1.

### DETAILED DESCRIPTION OF THE EXEMPLARY EMBODIMENTS

Hereinafter, exemplary embodiments of the present invention will be described with reference to the exemplary drawings. In the following description, the same elements will be designated by the same reference numerals although they are shown in different drawings. Further, in the following description of the present invention, a detailed description of known functions and configurations incorporated herein will be omitted when it may make the subject matter of the present invention rather unclear.

In addition, terms, such as first, second, A, B, (a), (b) or the like may be used herein when describing components of the present invention. Each of these terminologies is not used to define an essence, order or sequence of a corresponding component but used merely to distinguish the corresponding component from other component(s). It should be noted that if it is described in the specification that one component is “connected,” “coupled” or “joined” to another component, a third component may be “connected,” “coupled,” and “joined” between the first and second components, although the first component may be directly connected, coupled or joined to the second component.

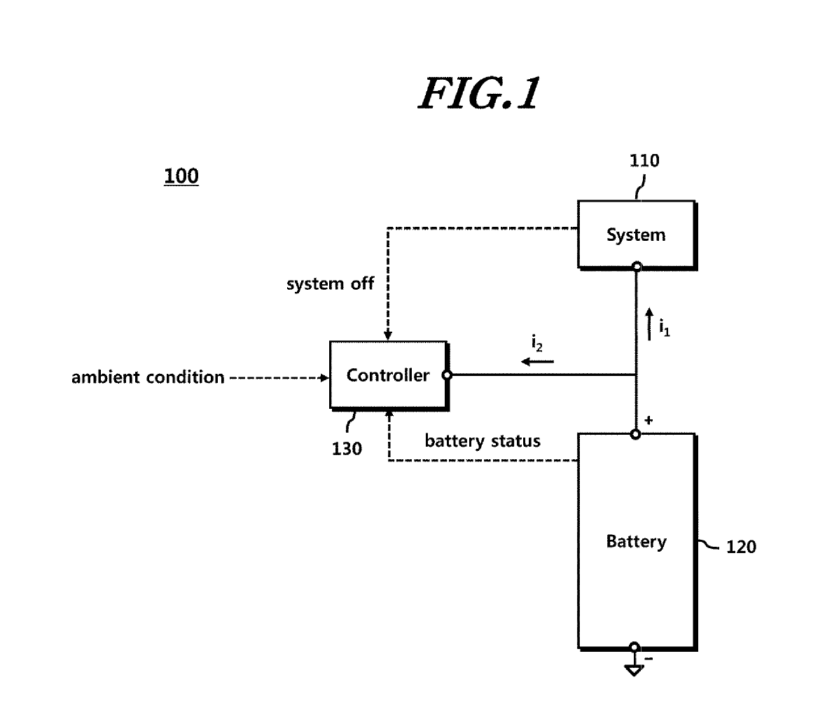

FIG. 1 is a diagram of an application according to an embodiment of the present invention.

Referring to FIG. 1, an application 100 may include a system 110, a battery 120, a controller 130, and the like.

The system 110, which is an electronic device using electric energy supplied from the battery 120, may include a mobile communication terminal, a tablet computer, an electric vehicle, and the like.

The battery 120 is a device for converting chemical energy into electrical energy, and Li-related batteries are notable examples. The battery 120 may be a 1-Cell Li-Ion battery, but the present invention may not be limited thereto.

The controller 130 is a device for controlling the battery 120, which monitors the status of the battery 120 and an ambient condition when the system 110 is turned off, and controls the battery 120 based on a result of the monitoring.

Referring to FIG. 1, in the application 100, the battery 120 may supply a current through two paths. When the system 110 is turned on, the battery 120 supplies a first current i₁ to the system 110. When the system is turned off and the battery 120 is in a predetermined status, the battery 120 may supply a second current i₂ to the controller 130. The provision of the second current i₂ from the battery 120 to the controller 130, seen from a different aspect, is the discharge of the second current i₂ from the battery 120 through the controller 130. Hereinafter, it will be described that the battery 120 discharges the second current i₂ through the controller 130.

When the battery 120 supplies the first current i₁ to the system 110, the controller 130 may control component elements of the battery 120 or the controller 130, so as to prevent the discharge of the second current i₂ through the controller 130. In an embodiment that does not require a control, the second current i₂ may be controlled irrespective of the first current i₁.

The controller 130 may control the battery 120 to discharge the second current i₂ in a predetermined condition.

The controller 130 may monitor the system 110, the status of the battery 120, and the ambient condition, so as to determine whether the predetermined condition is satisfied.

First, the controller 130 may monitor whether the system 110 is turned off or not.

Whether the system 110 is turned off may be monitored based on ON/OFF state information of the system 110, which is transferred from the system 110 to the controller 130.

Whether the system 110 is turned off may be determined through another method. For example, when the controller 130 monitors an amount of current supplied to the system 110, the controller 130 may indirectly estimate the ON/OFF state of the system 110 through the amount of current.

The controller 130 may monitor various statuses in association with the battery 120.

The controller 130 may monitor the temperature of the battery 120. The controller 130 may monitor the temperature of a package enclosing the battery 120, and may monitor the temperature inside the battery 120 through a temperature sensor included in the battery 120.

The controller 130 may monitor a terminal voltage of the battery 120. The controller 130 may measure the terminal voltage of the battery 120 through a path through which the second current i₂ is supplied.

The controller 130 may monitor an input/output current of the battery 120. The controller 130 may monitor the input/output current of the battery 120, including the first current i₁ and the second current i₂, through a current sensor.

The controller 130 may monitor a State-Of-Charge (SOC) of the battery 120. The controller 130 may include an SOC estimation algorithm, and may monitor the SOC of the battery 120 through the SOC estimation algorithm.

The controller 130 may monitor a State-Of-Health (SOH) of the battery 120. The controller 130 may include an algorithm for estimating the SOH using an SOC, a terminal voltage, an input/output current, and the like, and monitors the SOH of the battery 120 through the SOH estimation algorithm.

The controller 130 may monitor an ambient condition.

The controller 130 may monitor an ambient temperature as an ambient condition. The controller 130 may measure the temperature of a package enclosing the controller 130, so as to monitor the ambient temperature.

The controller 130 may monitor an ambient humidity.

The controller 130 may control the battery 120 to discharge the second current i₂ when the monitored values satisfy a predetermined condition.

In the embodiment of FIG. 1, when the system 110 is turned off and the terminal voltage of the battery 120 exceeds a reference voltage, the controller 130 may control the battery 120 so that the battery 120 discharges the second current i₂.

As another example, when the system 110 is turned off and the temperature of the battery 120 exceeds a reference temperature, the controller 130 may control the battery 120 so that the battery 120 discharges the second current i₂.

As another example, when the system 110 is turned off and the SOC of the battery 120 exceeds a reference SOC, the controller 130 may control the battery 120 so that the battery 120 discharges the second current i₂.

As another example, when the system 110 is turned off and an ambient temperature exceeds a reference temperature, the controller 130 may control the battery 120 so that the battery 120 discharges the second current i₂.

Hereinafter, for ease of description, it will be described that the controller 130 monitors the OFF state of the system 110, the terminal voltage of the battery 120, and the ambient temperature, and determines whether to discharge the battery 120 based on the monitored value. However, the present invention may not be limited thereto.

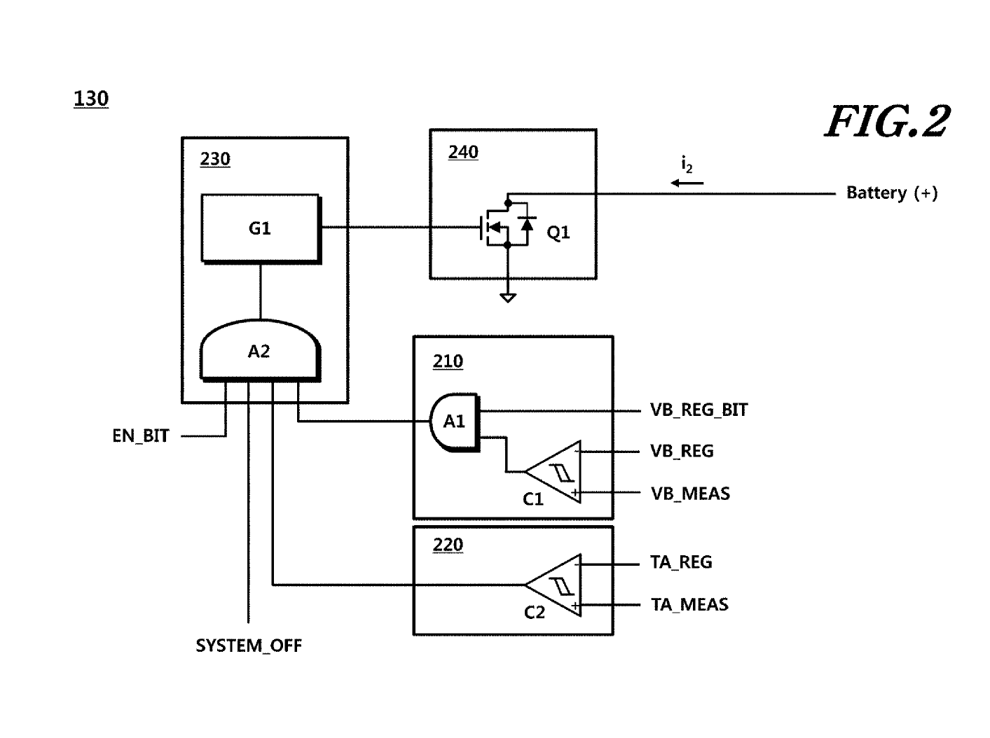

FIG. 2 is a diagram of an example of the controller 130 of FIG. 1.

Referring to FIG. 2, the controller 130 may include a first logic circuit 210 that includes a first comparer C1 which compares two input signals and outputs a high or low level signal, and executes a logic operation, a second logic circuit 220 that includes a second comparer C2 and executes a logic operation, a discharge circuit 240 that provides a discharge path, a discharge control circuit 230 that controls the discharge circuit 240, and the like.

The first logic circuit 210 may output a result of comparing a measurement value VB_MEAS of the terminal voltage of the battery 120 and a reference voltage VB_REG.

To this end, the first logic circuit 210 may include the first comparer C1, and the measurement value VB_MEAS of the terminal voltage of the battery 120 is input into a plus terminal of the first comparer C1, and the reference voltage VB_REF is input into a minus terminal. In this instance, when the measurement value VB_MEAS of the terminal voltage of the battery 120 exceeds the reference voltage VB_REG, the first comparer C1 may output a high level signal.

The inputs of the first comparer C1 may be connected reversely. For example, the reference voltage VB_REG may be input into the plus terminal, and the measurement value VB_MEAR of the terminal voltage of the battery 120 may be input into the minus terminal. In this instance, when the measurement value VB_MEAS of the terminal voltage of the battery 120 exceeds the reference voltage VB_REG, the first comparer C1 may output a low level signal.

The first logic circuit 210 may further include a first AND logic A1. An output of the first comparer C1 and a voltage regulation bit value VB_REG_BIT may be input into the first AND logic A1. When the voltage regulation bit value VB_REG_BIT indicates a low level, the first AND logic A1 outputs a low level although the output of the first comparer C1 indicates a high level.

The second logic circuit 220 outputs a result of comparing a measurement value TA_MEAS of an ambient temperature with a reference temperature TA_REG.

To this end, the second logic circuit 220 may include the second comparer C2, and the measurement value TA_MEAS of the ambient temperature is input into a plus terminal of the second comparer C2, and the reference temperature TA_REG is input into a minus terminal. In this instance, when the ambient temperature measurement value TA_MEAS exceeds the reference temperature TA₁₃ REG, the second comparer C2 may output a high level signal.

The discharge circuit 240 includes a switch, and may control the battery 120 to be discharged when a predetermined condition is satisfied. In addition, the discharge circuit 240 may include a load that may consume a current that is discharged from the battery 120.

In the embodiment of FIG. 2, the discharge circuit 240 may include a first power switch Q1 which may simultaneously execute functions of a switch and a load.

The discharge control circuit 230 may determine whether a predetermined condition is satisfied based on values obtained through monitoring by the controller 130, and when the predetermined condition is satisfied, controls the discharge circuit 240 so as to discharge the battery 120.

In the embodiment of FIG. 2, the discharge control circuit 230 includes a third logic circuit which receives an output signal of the first logic circuit 210, an output signal of the second logic circuit 220, an enable bit signal EN_BIT, and an ON/OFF state signal SYSTEM_OFF of the system 110 as an input, and a gate driving circuit G1 that drives a gate of the first power switch Q1. In FIG. 2, the third logic circuit may be embodied as a second AND logic A2.

The enable bit EN_BIT is a signal to determine whether the discharge control circuit 230 operates or not, and when the enable bit EN_BIT has a value of a low level, the discharge control circuit 230 may control the battery 120 to not discharge the second current i₂.

SYSTEM_OFF is an ON/OFF state signal of the system 110, and may have a high level value when the system 110 is turned on, and may have a low level value when the system 110 is turned off.

SYSTEM_OFF signal may be generated when a power-hold signal is low, a reset signal is low or a system I/O supply signal is low. And SYSTEM_OFF signal itself may be the power-hold signal, the reset signal or the system I/O supply signal.

In the embodiment of FIG. 2, when an enable bit EN_BIT has a high level value, the system 110 is turned off, and both the output signal of the first logic circuit 210 and the output signal of the second logic circuit 220 have high level values, then the second AND logic A2 outputs a high level signal.

In the embodiment of FIG. 2, when a high level signal is received from the second AND logic A2, the gate driving circuit G1 outputs, to a gate of the first power switch Q1, a voltage for turning the first power switch Q1 on. When the first power switch Q1 is an N type Field Effect Transistor (FET), the gate driving circuit G1 may output a high voltage to the gate of the first power switch Q1.

When the embodiment of FIG. 2 is seen from the perspective of a signal, the first logic circuit 210 outputs a first signal when a terminal voltage of the battery 120 exceeds a reference voltage. In this instance, the first signal is a high level signal. In addition, the second logic circuit 220 outputs a second signal when an ambient temperature exceeds a reference temperature, and the second signal is also a high level signal, like the first signal.

The third logic circuit (A2 in FIG. 2) executes AND operation on an enable signal, an ON/OFF state signal SYSTEM_OFF of the system 110, an output signal of the first logic circuit 210, and an output signal of the second logic circuit 220. From the perspective of a signal, the third logic circuit (A2 of FIG. 2) outputs a third signal of a high level, when the system 110 is turned off and the first signal and the second signal are received.

When the third signal is received, the gate driving circuit G1 outputs, to the gate of the first power switch Q1, a voltage for turning the first power switch Q1 on.

Meanwhile, the first comparer C1 and the second comparer C2 may have a hysteresis property.

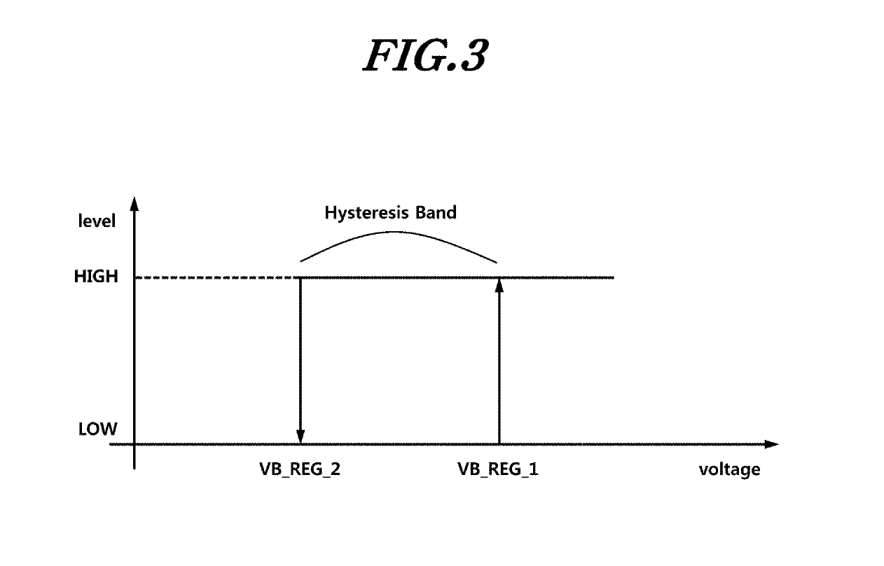

FIG. 3 is a graph illustrating a hysteresis property of the battery voltage comparer C1 of FIG. 2.

Referring to FIG. 3, the first comparer C1 may include a hysteresis band between a first reference voltage VB_REG_1 and a second reference voltage VB_REG_2.

When it is assumed that the first comparer C1 outputs a low level signal, the first comparer C1 changes an output signal to a high level signal when a measurement value VB_MEAS of a terminal voltage of the battery 120 exceeds the first reference voltage VB_REG_1.

Once the first comparer C1 outputs a high level signal, the first comparer C1 continuously outputs a high level signal within a predetermined range although the measurement value VB_MEAS of the terminal voltage of the battery 120 becomes lower than or equal to the first reference voltage VB_REG_1.

In a state in which a high level signal is output, when the measurement value VB MEAS of the terminal voltage of the battery 120 becomes lower than or equal to the second reference voltage VB_REG_2, the first comparer C1 changes an output signal into a low level signal.

The second comparer C2 may have a hysteresis property, like the first comparer C1. The second comparer C2 has a hysteresis band, and changes an output signal when a measurement value TB_MEAS of an ambient temperature exceeds the highest value of the hysteresis band or becomes lower than or equal to the lowest value of the hysteresis band.

The features of the discharge circuit 240 of FIG. 2 will be described in detail.

Referring again to FIG. 2, the discharge circuit 240 includes the first power switch Q1, and controls the discharge of the battery 120 using a switch-feature of the first power switch Q1, and consumes a discharge current using a load-feature of the first power switch Q1.

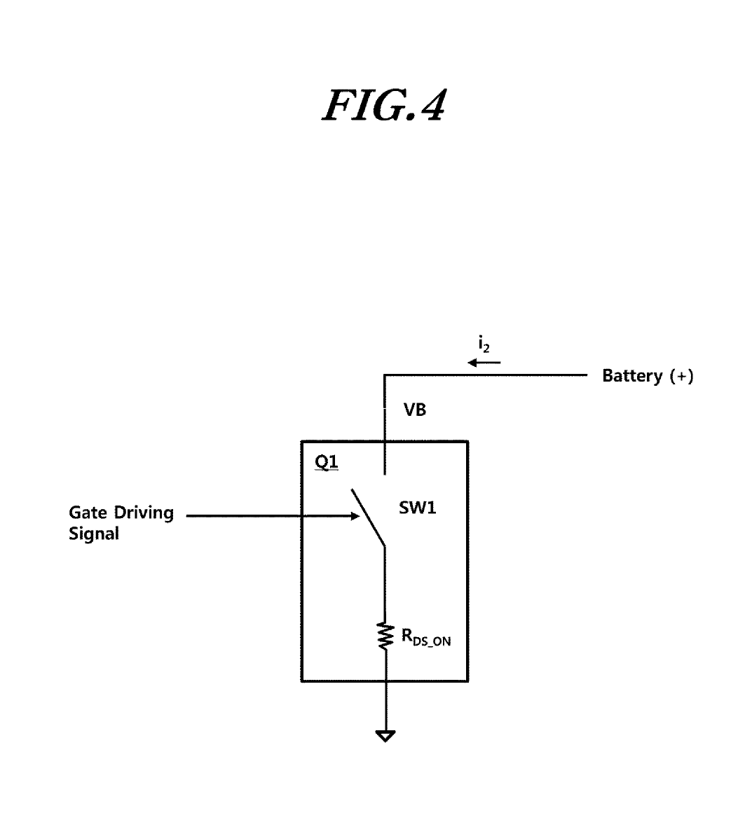

FIG. 4 is a diagram illustrating a circuit model of the power switch Q1 of FIG. 2.

Referring to FIG. 4, the first power switch Q1 of FIG. 2 may be modeled using a switch SW1 and an on-state resistance R_{DS}_{_}_{ON}. The on-state resistance is a resistance between a drain and a source of the first power switch Q1, and is measured when the first power switch is turned on.

When a gate driving signal of the gate driving circuit G1 is transferred to a gate of the first switch Q1, the switch SW1 is turned on and a plus terminal of the battery 120 is connected to the on-state resistance R_{DS}_{_}_{ON}.

In this instance, a second current i₂ of Equation 1 may flow through the on-state resistance R_{DS}_{_}_{ON}.

i₂=VB/R_{DS}_{_}_{ON}(VB is a terminal voltage of the battery 120) [Equation 1]

The on-state resistance R_{DS}_{_}_{ON} limits a scale of the second current i₂ to be less than or equal to a predetermined value and thus, the controller 130 may control the power that is to be consumed in a discharge path to be less than or equal to a predetermined value.

For example, when the on-state resistance R_{DS}_{_}_{ON} is 80Ω(ohm) and a maximum value of the terminal voltage VB of the battery 120 is 5V, the second current i₂ may be limited to be less than or equal to 62.5 mA. Accordingly, the power consumed in the discharge path may be controlled to be less than or equal to 312.5 mW.

The discharge circuit may be provided in a different shape, in addition to the shape of the discharge circuit 240 of FIG. 2.

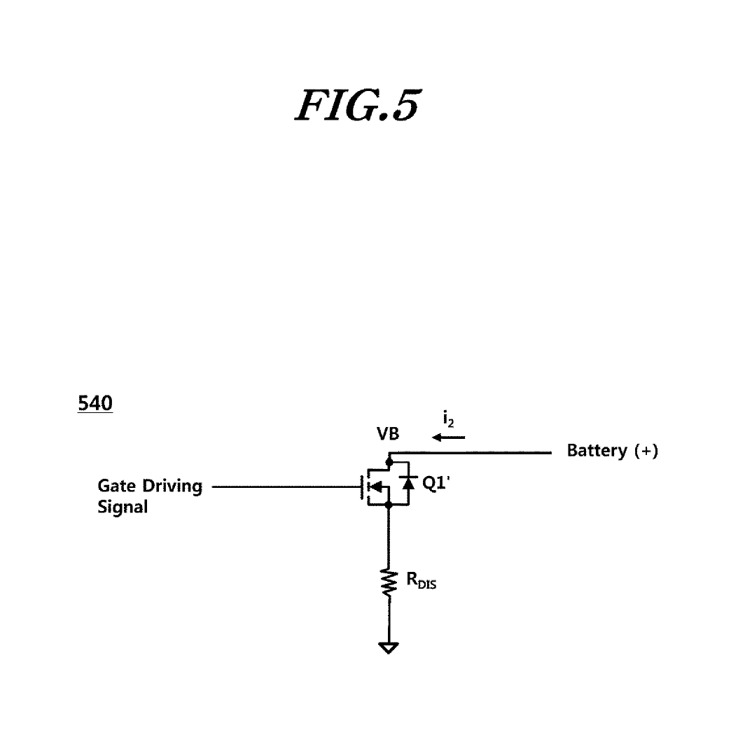

FIG. 5 is a diagram of another example of a discharge circuit.

Referring to FIG. 5, a discharge circuit 540 according to another example may include a power switch Q1′ and a discharge resistance R_{DIS}.

In the example of FIG. 5, the power switch Q1′ may have an on-state resistance. Accordingly, a discharge current i₂ of the battery 120 may be consumed by the power switch Q1′ and the discharge resistance R_{DIS}.

When the on-state resistance of the power switch Q1′ is smaller than the discharge resistance R_{DIS}, the discharge current i₂ may be mainly consumed in the discharge resistance R_{DIS}.

When power is consumed, heat is generated. Accordingly, in the embodiment of FIG. 4, a heat dissipation device (for example, a heat sink, a heat dissipation pad, and the like) may be attached to the first power switch Q1. In the embodiment of FIG. 5, a heat dissipation device may be attached to the discharge resistance R_{DIS}.

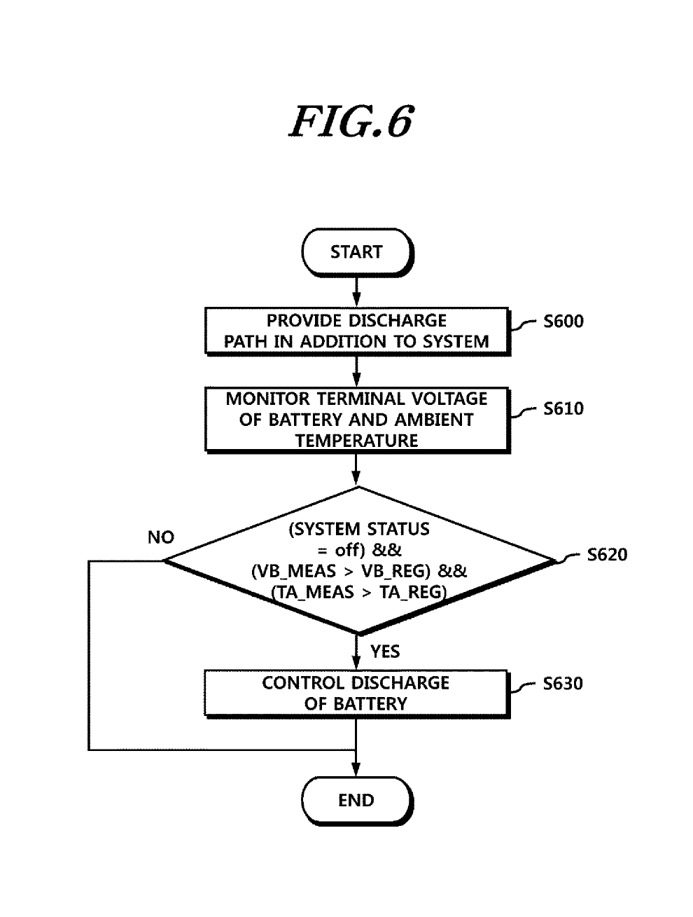

FIG. 6 is a flowchart of an example of a battery controlling method.

Referring to FIG. 6, the application 100 is provided with a discharge path in addition to the system 110, in operation S600. As an example of the discharge path, the discharge circuit 240 is illustrated in FIG. 2.

The controller 130 monitors an ON/OFF state of the system 110, a terminal voltage of the battery 120, and an ambient temperature in operation S610.

When the system 110 is turned off, the terminal voltage of the battery 120 exceeds a first reference voltage VB_REG_1, and the ambient temperature exceeds a reference temperature (YES in operation S620) based on monitored values, the controller 130 executes a control on the discharge of the battery 120, in operation S630.

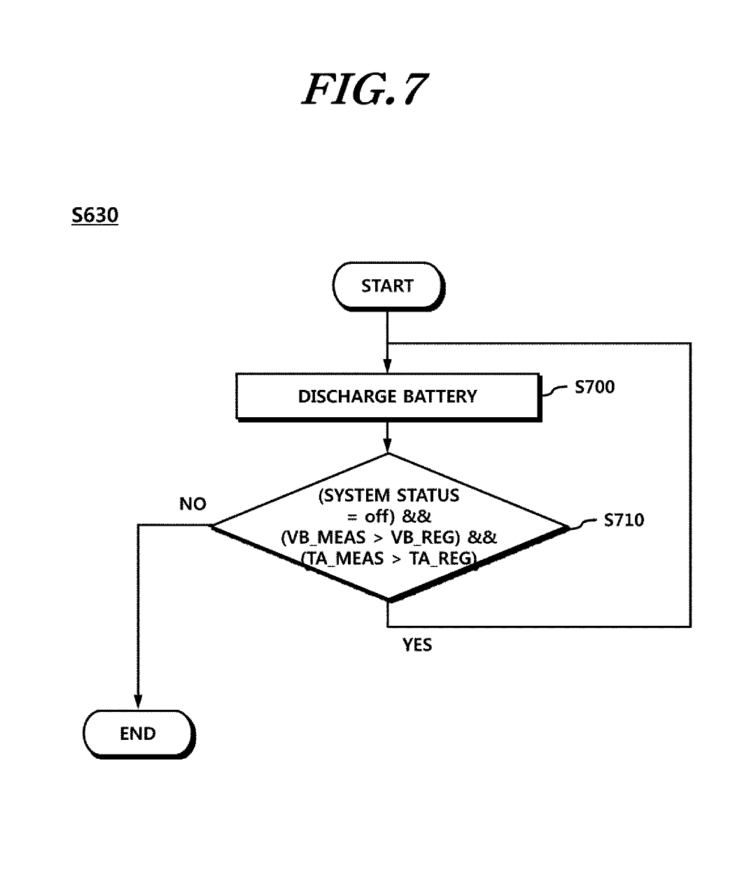

FIG. 7 is a diagram of an example of a battery discharge controlling operation S630.

In the discharge controlling operation S630, the controller 130 may discharge the battery 120 through a discharge path in operation S700.

When the discharge path is provided in the application 100, as shown in the embodiment of FIG. 2 or FIG. 4, the controller 130 may discharge the battery 120 through a resistance between a drain and a source of the power switch Q1 disposed in the discharge path.

When the switch Q1′ and the discharge resistance R_{DIS} are disposed in the discharge path as shown in the embodiment of FIG. 5, the controller 130 may turn the switch Q1′ on and connect the discharge resistance R_{DIS} to a terminal of the battery 120, so as to discharge the battery 120.

In this instance, the controller 130 may control the power that may be consumed in the discharge path to be less than or equal to a predetermined value.

In the discharge controlling operation S630, the status of the system 110 and the status of the battery 120 are continuously monitored as the battery 120 discharges in operation S700. When the system 110 is turned off, a terminal voltage of the battery 120 exceeds a first reference voltage VB_REG_1, and an ambient temperature exceeds a reference temperature (YES in operation S710) based on a result of monitoring, the controller 130 continuously discharges the battery 120 in operation S700. Otherwise (No in operation S710), the controller 130 terminates the discharge controlling operation S630.

Operation S710 may include a hysteresis control. In this instance, the controller 130 may discontinue the discharge of the battery 120 when the terminal voltage of the battery 120 is dropped to be less than or equal to a second reference voltage VB_REG_2 which is lower than the first reference voltage VB_REG_1. Otherwise, the controller 130 may maintain the discharge of the battery 120.

The controller 130 may further include a charging circuit for charging the battery 120 and a fuel gauge for measuring an SOC of the battery 120.

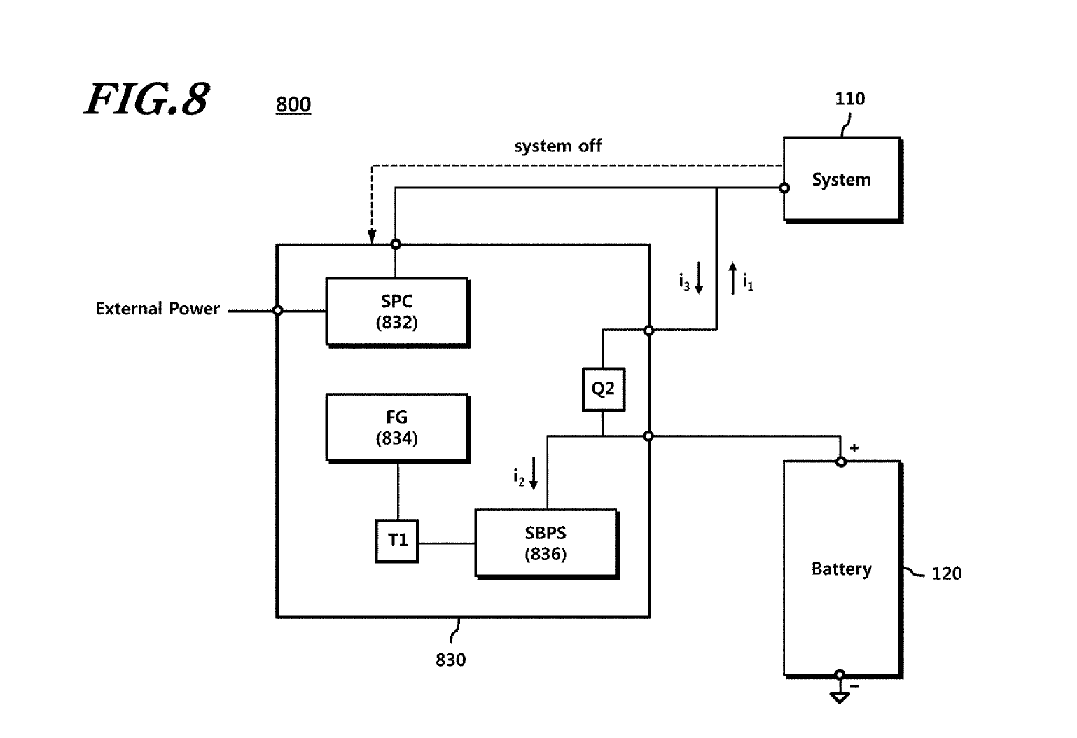

FIG. 8 is a diagram of an application according to another embodiment of the present invention.

Referring to FIG. 8, an application 800 may include the system 110, the battery 120, and a controller 830 according to another embodiment.

In FIG. 8, the controller 830 may include a charging circuit 832, a fuel gauge 834, and a battery controlling circuit 836.

The charging circuit 832 converts external power and supplies the converted power to the system 110, or supplies a charge current i₃ to the battery 120.

The fuel gauge 834 is a block for measuring the SOC of the battery 120, and may estimate the SOC of the battery 120 using an input/output current of the battery 120, a terminal voltage of the battery 120, and an ambient temperature. In some embodiments, the fuel gauge 834 may further measure an SOH.

The battery control circuit 836 is a circuit for controlling the battery 120 to discharge a second current i₂ under a predetermined condition, and embodiments of the controller 130 which have been described with reference to FIGS. 1 to 7 may be applied.

The controller 830 according to another embodiment may further include a temperature sensor T1.

A measurement value of the temperature sensor T1 may be used in the fuel gauge 834. The fuel gauge 834 may estimate an internal resistance of the battery 120, and may correct or estimate the SOC using the internal resistance. In this instance, the internal resistance of the battery 120 may have a different value based on a temperature, and the fuel gauge 834 may more accurately estimate the internal resistance of the battery 120 using the value measured by the temperature sensor T1.

The measurement value of the temperature sensor T1 may also be used by the battery control circuit 836.

The controller 130 of FIG. 1 may discharge the battery 120 when the ambient temperature exceeds a reference temperature. In this manner, the battery control circuit 836 may discharge the battery 120 when a value measured by the temperature sensor T1 exceeds the reference temperature.

The value measured by the single temperature sensor T1 may be used by two blocks 834 and 836 of the controller 830.

The measurement value of the terminal voltage of the battery 120 may be commonly used in both the fuel gauge 834 and the battery control circuit 836.

The fuel gauge 834 may estimate the SOC using the terminal voltage of the battery 120. For example, the fuel gauge 834 may store a correlation function between the terminal voltage of the battery 120 and the SOC, and the fuel gauge 834 may estimate the SOC by substituting the measurement value of the terminal voltage of the battery 120 to the function.

The battery control circuit 836 may also use the terminal voltage of the battery 120.

The controller 130 of FIG. 1 may discharge the battery 120 when the terminal voltage of the battery 120 exceeds a reference voltage. In this manner, the battery control circuit 836 may discharge the battery 120 when the terminal voltage of the battery 120 exceeds the reference voltage.

The controller 830 according another embodiment may further include the charging circuit 832. In this instance, when the battery control circuit 836 discharges the battery 120 while the charging circuit 832 supplies the charge current i₃ to the battery 120, this may cause a problem. In this instance, the second current i2 that flows through the controller 830 may partially include the charge current i₃ of the battery 120 and thus, charging may be inefficiently executed or the discharge of the battery 120 may not be executed.

The controller 830 may set an enable bit signal EN_BIT to a low level when the charging circuit 832 supplies the charge current i₃ to the battery 120. The above described scheme gives a priority to charging, and prevents the flow of the second current i₂ while the charge current i₃ is supplied.

As another method, the controller 830 may execute a control to prevent the flow of the charge current i₃ while the battery 120 discharges through the battery control circuit 836.

The controller 830 controls the charging circuit 832 in addition to the battery control circuit 836 and thus, the controller 830 may control the charging circuit 832 to prevent the flow of the charge current i₃ while the battery 120 discharges through the battery control circuit 836.

From the perspective of hardware, the controller 830 may separate the charge current i₃ and the second current i₂. To this end, the controller 830 may further include the second power switch Q2, as shown in the embodiment of FIG. 8.

Referring to FIG. 8, the second power switch Q2 is disposed in a path through which the charge current i₃ is supplied to the battery 120. Accordingly, the controller 830 may turn a second power switch Q2 off so as to control the charge current i₃ to not be supplied to the battery 120 while the battery control circuit 836 discharges the battery 120.

When the second power switch Q2 is disposed in a path of the first current i₁ through which the battery 120 supplies power to the system 110, in addition to the path of the charge current i₃, as shown in FIG. 8, the controller 830 may turn the second power switch Q2 off so as to cut the spread of the discharge effects generated by the battery control circuit 836, to the system 110.

Here, the discharge effects may be generated as the battery 120 discharges through the battery control circuit 836. A representative example of the discharge effects is that the voltage of the battery 120 becomes lower. In addition, an effect generated as the battery control circuit 836 malfunctions may be included in those effects.

It is desirable that the spread of the effects to the system 110 is prevented. The second power switch Q2 is disposed in the path of the first current i₁ and thus, it may cut the spread of the effects.

The battery controlling method that has been described with reference to FIG. 6 may further include operations for preventing conflict with the charging circuit 832.

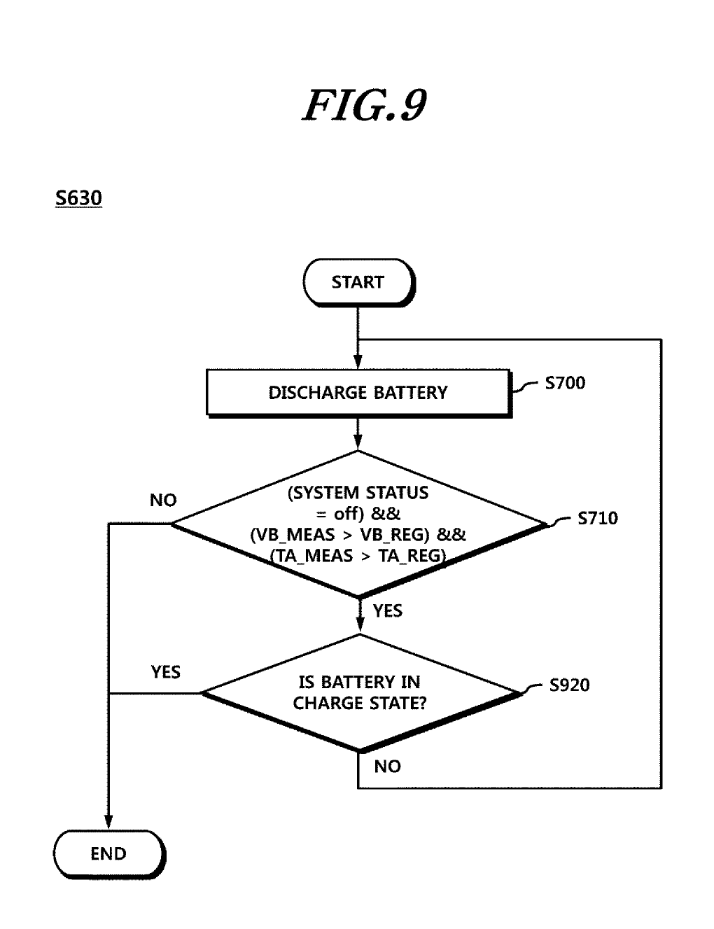

FIG. 9 is a diagram of another example of the battery discharge controlling operation of FIG. 6.

Referring to FIG. 9, the discharge controlling operation S630 may further include operation S920 in addition to operations S700 and S710 which have been described with reference to FIG. 7.

The battery controlling method that has been described with reference to FIG. 6 may be applied to the controller 830 according to another embodiment. When the charging circuit 832 is further added to the controller 830, operation S920 may be further added as shown in FIG. 9.

In particular, in operation S630, the controller 830 may discharge the battery 120 through a discharge path in operation S700.

When the system 110 is turned off, the terminal voltage of the battery 120 exceeds a first reference voltage VB_REG_1, and an ambient temperature exceeds a reference temperature (YES in operation S710) based on a result of continuous monitoring of a status of the system 110 and a status of the battery 120, the controller 830 determines whether the battery 120 is in a charge state in operation S920.

When the battery 120 is not in a charge state in operation S920 (No in operation S920), the controller 830 continuously discharges the battery 120 in operation S700. Otherwise (YES in operation S920), the controller 830 terminates the discharge controlling operation S630.

The battery controlling method that has been described with reference to FIG. 6 may further include an operation (not illustrated) of supplying a charging power to the battery 120. In this instance, the controller 830 may control the battery control circuit 836 to prevent the flow of the charge current i3 to a discharge path in the operation (not illustrated) of supplying the charging power to the battery 120, so as to prevent the conflict with the charging circuit 832.

The charging circuit 832 may be a switch-mode charging circuit, and the controller 830 may be an integrated circuit including the switch-mode charging circuit.

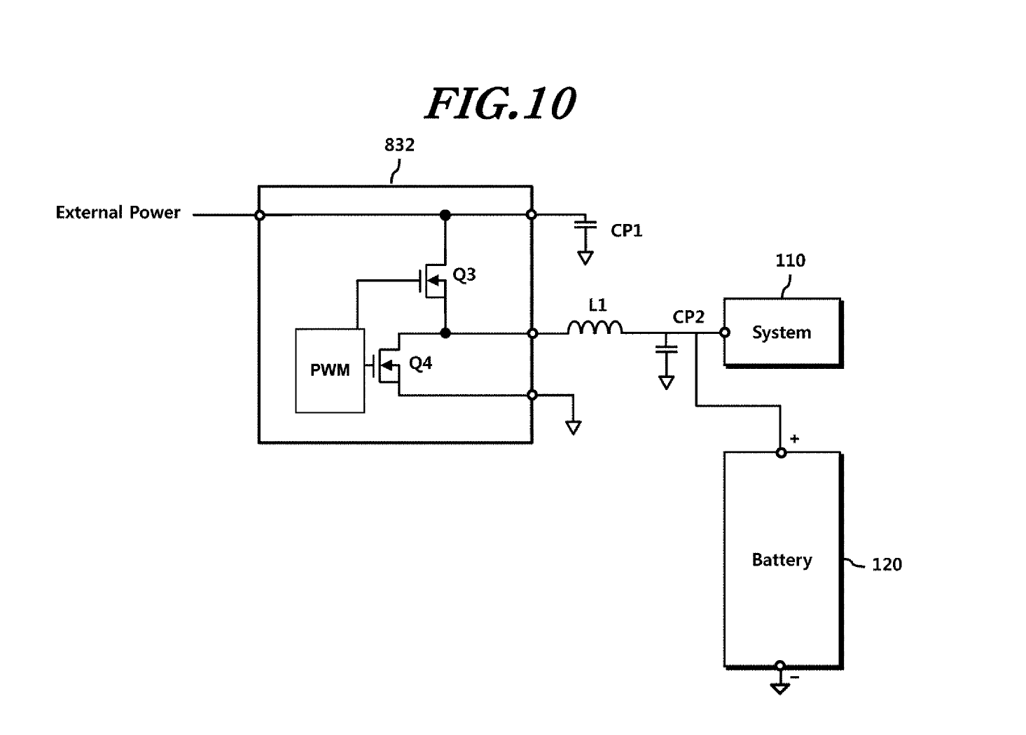

FIG. 10 is a diagram of an example of a switch-mode charging circuit.

Referring to FIG. 10, the charging circuit 832 may include a third power switch Q3, a fourth power switch Q4, and a control circuit PWM for controlling the power switches.

Although a synchronous buck type converter circuit that uses two power switches Q3 and Q4 is disclosed in the example of the charging circuit 832 of FIG. 10, the charging circuit 832 is not limited thereto and another type of converter circuit may be used.

The charging circuit 832 may control a voltage by receiving feedback associated with an output voltage formed in an output capacitor CP2. However, the output voltage may be a value identical to the terminal voltage of the battery 120 that is used by the battery control circuit 836 and thus, the charging circuit 832 may use the terminal voltage of the battery 120 as a voltage feedback signal. In this instance, the charging circuit 832 and the battery control circuit 836 may share a single measurement value of the terminal voltage of the battery 120.

The power switches Q3 and Q4 used for the charging circuit 832 may be of the same type as the first power switch Q1 of FIG. 1. For example, all of the first power switch Q1, the third power switch Q3, and the fourth power switch Q4 may be Field Effect Transistors (FETs). When the power switches Q1, Q3, and Q4 are of the same type, each of the power switches Q1, Q3, and Q4 may be manufactured through an identical process.

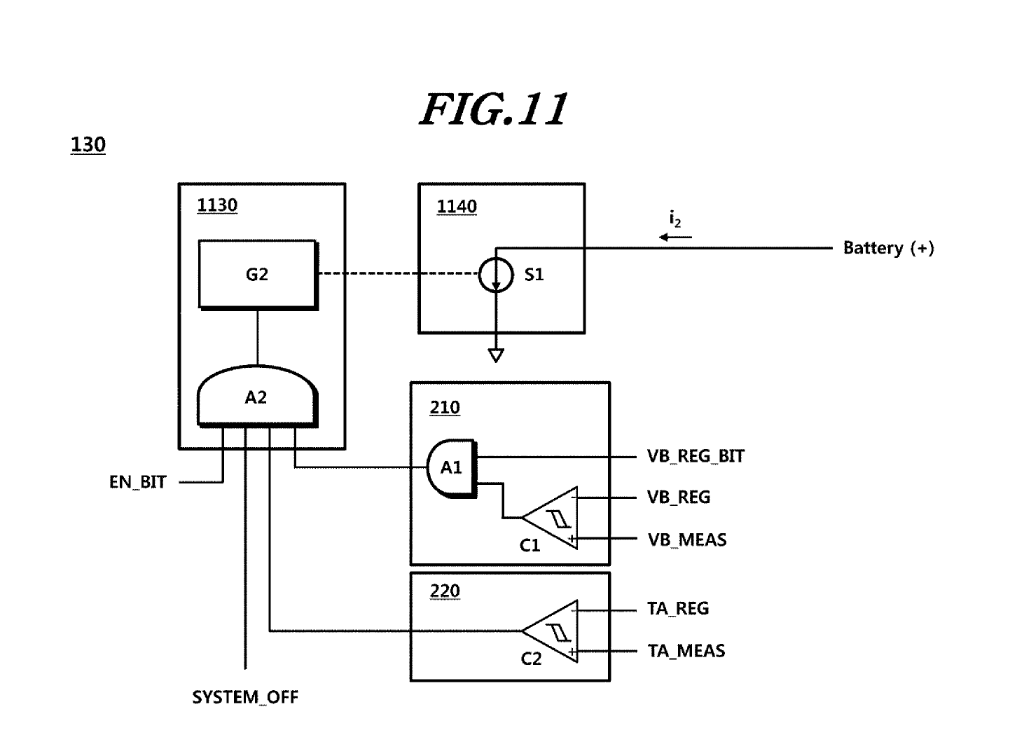

FIG. 11 is a diagram of another example of the controller 130 of FIG. 1.

Referring to FIG. 11, the controller 130 may include a first logic circuit 210 that includes a first comparer C1 which compares two input signals and outputs a high or low level signal, and executes a logic operation, a second logic circuit 220 that includes a second comparer C2 and executes a logic operation, a discharge circuit 1140 that provides a discharge path, a discharge control circuit 1130 that controls the discharge circuit 1140, and the like.

The first logic circuit 210 may output a result of comparing a measurement value VB_MEAS of the terminal voltage of the battery 120 and a reference voltage VB_REG.

To this end, the first logic circuit 210 may include the first comparer C1, and the measurement value VB_MEAS of the terminal voltage of the battery 120 is input into a plus terminal of the first comparer C1, and the reference voltage VB_REF is input into a minus terminal. In this instance, when the measurement value VB_MEAS of the terminal voltage of the battery 120 exceeds the reference voltage VB_REG, the first comparer C1 may output a high level signal.

The first logic circuit 210 may further include a first AND logic A1. An output of the first comparer C1 and a voltage regulation bit value VB_REG_BIT may be input into the first AND logic A1. When the voltage regulation bit value VB_REG_BIT indicates a low level, the first AND logic A1 outputs a low level although the output of the first comparer C1 indicates a high level.

The second logic circuit 220 outputs a result of comparing a measurement value TA_MEAS of an ambient temperature with a reference temperature TA_REG.

To this end, the second logic circuit 220 may include the second comparer C2, and the measurement value TA_MEAS of the ambient temperature is input into a plus terminal of the second comparer C2, and the reference temperature TA_REG is input into a minus terminal. In this instance, when the ambient temperature measurement value TA_MEAS exceeds the reference temperature TA_REG, the second comparer C2 may output a high level signal.

The discharge circuit 1140 includes a current source S1, and may control the battery 120 to be discharged when a predetermined condition is satisfied. In some cases, the current source S1 may be called as a current sink.

The discharge control circuit 1130 may determine whether a predetermined condition is satisfied based on values obtained through monitoring by the controller 130, and when the predetermined condition is satisfied, controls the discharge circuit 1140 so as to discharge the battery 120.

In the embodiment of FIG. 11, the discharge control circuit 1130 includes a third logic circuit which receives an output signal of the first logic circuit 210, an output signal of the second logic circuit 220, an enable bit signal EN_BIT, and an ON/OFF state signal SYSTEM_OFF of the system 110 as an input, and a control circuit G2 that controls the current source S1. In FIG. 11, the third logic circuit may be embodied as a second AND logic A2.

The enable bit EN_BIT is a signal to determine whether the discharge control circuit 1130 operates or not, and when the enable bit EN_BIT has a value of a low level, the discharge control circuit 1130 may control the battery 120 to not discharge the second current i₂.

SYSTEM_OFF is an ON/OFF state signal of the system 110, and may have a high level value when the system 110 is turned on, and may have a low level value when the system 110 is turned off.

In the embodiment of FIG. 11, when an enable bit EN_BIT has a high level value, the system 110 is turned off, and both the output signal of the first logic circuit 210 and the output signal of the second logic circuit 220 have high level values, then the second AND logic A2 outputs a high level signal.

In the embodiment of FIG. 11, when a high level signal is received from the second AND logic A2, the control circuit G2 outputs, to the current source S1, a signal for operating the current source S1.

When the embodiment of FIG. 11 is seen from the perspective of a signal, the first logic circuit 210 outputs a first signal when a terminal voltage of the battery 120 exceeds a reference voltage. In this instance, the first signal is a high level signal. In addition, the second logic circuit 220 outputs a second signal when an ambient temperature exceeds a reference temperature, and the second signal is also a high level signal, like the first signal.

The third logic circuit (A2 in FIG. 11) executes AND operation on an enable signal, an ON/OFF state signal SYSTEM_OFF of the system 110, an output signal of the first logic circuit 210, and an output signal of the second logic circuit 220. From the perspective of a signal, the third logic circuit (A2 of FIG. 11) outputs a third signal of a high level, when the system 110 is turned off and the first signal and the second signal are received.

When the third signal is received, the control circuit G2 outputs, to the current source S1, a signal for turning the current source S1 on.

As described above, according to embodiments of the present invention, a status of a battery may be monitored while the system is turned off, and the battery may be discharged based on a result of the monitoring, so as to make the battery stable.

In addition, since terms, such as “including,” “comprising,” and “having” mean that one or more corresponding components may exist unless they are specifically described to the contrary, it shall be construed that one or more other components can be included. All of the terminologies containing one or more technical or scientific terminologies have the same meanings that persons skilled in the art understand ordinarily unless they are not defined otherwise. A term ordinarily used like that defined by a dictionary shall be construed that it has a meaning equal to that in the context of a related description, and shall not be construed in an ideal or excessively formal meaning unless it is clearly defined in the present specification.

Although a preferred embodiment of the present invention has been described for illustrative purposes, those skilled in the art will appreciate that various modifications, additions and substitutions are possible, without departing from the scope and spirit of the invention as disclosed in the accompanying claims. Therefore, the embodiments disclosed in the present invention are intended to illustrate the scope of the technical idea of the present invention, and the scope of the present invention is not limited by the embodiment. The scope of the present invention shall be construed on the basis of the accompanying claims in such a manner that all of the technical ideas included within the scope equivalent to the claims belong to the present invention.

What is claimed is:

1. A device for controlling a battery that supplies power to a system, comprising:
a first power switch that is connected to a terminal of the battery and has an on-state resistance;
a first logic circuit that outputs a first signal when the terminal voltage of the battery exceeds a reference voltage;
a second logic circuit that outputs a second signal when an ambient temperature exceeds a reference temperature; and
a discharge control circuit that turns the first power switch on when the system is turned off and the first signal and the second signal are received, so as to discharge the battery.

2. The device of claim 1, wherein the discharge control circuit includes a gate driving circuit and a third logic circuit;
the third logic circuit outputs a third signal when the system is turned off and the first signal and the second signal are received; and
the gate driving circuit outputs, to a gate of the first power switch, a voltage for turning the first power switch on when the third signal is received.

3. The device of claim 2, wherein the first logic circuit and the second logic circuit are comparer circuits that compare two input signals and output a high or low level signal; and
the third logic circuit is an AND logic circuit.

4. The device of claim 3, wherein the third logic circuit executes an AND operation on the first signal, the second signal, a signal indicating an ON/OFF state of the system, and an enable-bit signal associated with the discharge control circuit.

5. The device of claim 4, further comprising:
a charging circuit that supplies charging power to the battery,
wherein the enable-bit signal is set to a low level when the charging circuit supplies a charging current to the battery.

6. The device of claim 1, wherein the first logic circuit includes a hysteresis circuit, and changes an output signal when the terminal voltage of the battery is out of a hysteresis zone.

7. The device of claim 1, wherein the discharge control circuit turns the first power switch off when the first signal or the second signal is not received after the first power switch is turned on.

8. The device of claim 1, wherein the device corresponds to an integrated circuit that further comprises a switch-mode charging circuit; and
the switch-mode charging circuit controls a charging current using power switches which are of the same type as the first power switch.

9. The device of claim 1, further comprising:
a second power switch disposed between the first power switch and the system,
wherein the second power switch cuts the spread of a discharging effect, incurred by the first power switch, to the system.

10. The device of claim 1, further comprising:
a fuel gauge that estimates a State Of Charge (SOC) of the battery,
wherein the fuel gauge uses a measurement value of the terminal voltage of the battery and a measurement value of the ambient temperature, for estimating the SOC.

11. A method of controlling a battery that supplies power to a system, the method comprising:
providing a discharge path, outside of the system;
monitoring an ON/OFF state of the system, a terminal voltage of the battery, and an ambient temperature; and
discharging the battery through the discharge path when the system is turned off, the terminal voltage of the battery exceeds a first reference voltage, and the ambient temperature exceeds a reference temperature.

12. The method of claim 11, wherein discharging the battery comprises:
discharging the battery through a resistance between a drain and a source of a power switch disposed in the discharge path.

13. The method of claim 11, wherein a switch and a discharge resistance are disposed in the discharge path; and
discharging the battery comprises:
turning the switch on so as to connect the discharge resistance to the terminal of the battery.

14. The method of claim 11, further comprising:
discontinuing the discharge of the battery when the terminal voltage of the battery is dropped to be less than or equal to a second reference voltage while the battery is being discharged.

15. The method of claim 11, wherein discharging the battery comprises:
blocking a path through which power is supplied to the system.

16. The method of claim 11, further comprising:
estimating a State Of Charge (SOC) of the battery using an input/output current of the battery, the terminal voltage of the battery, and the ambient temperature.

17. The method of claim 11, further comprising:
supplying charging power to the battery through a charging circuit,
wherein supplying the charging power to the battery comprises controlling the charging current to not be supplied to the discharge path.

18. A device for controlling a battery that supplies power to a system, comprising:
a current source that is connected to a terminal of the battery and has an on-state resistance;
a first logic circuit that outputs a first signal when the terminal voltage of the battery exceeds a reference voltage;
a second logic circuit that outputs a second signal when an ambient temperature exceeds a reference temperature; and
a discharge control circuit that controls the current source when the system is turned off and the first signal and the second signal are received, so as to discharge the battery.

19. The device of claim 18, further comprising:
a switch disposed between the current source and the system,
wherein the switch cuts the spread of a discharging effect, incurred by the current source, to the system.

20. The device of claim 18, further comprising:
a fuel gauge that estimates a State Of Charge (SOC) of the battery,
wherein the fuel gauge uses a measurement value of the terminal voltage of the battery and a measurement value of the ambient temperature, for estimating the SOC.
